(19) United States
(12) Patent Application Publication
(10) Pub. No.: US 2016/0372650 A1
(43) Pub. Date: Dec. 22, 2016

(54) THERMOELECTRIC DEVICE FOR HIGH TEMPERATURE APPLICATIONS

(71) Applicant: Sheetak Inc., Austin, TX (US)

(72) Inventors: Uttam GHOSHAL, Austin, TX (US); Ravi PRASHER, Austin, TX (US); Ayan GUHA, Austin, TX (US)

(73) Assignee: Sheetak Inc.

(21) Appl. No.: 14/742,364

(22) Filed: Jun. 17, 2015

(51) Int. Cl. H01L 35/08; H01L 35/32; H01L 35/34; F25B 21/02

(52) U.S. Cl. CPC H01L 35/08; F25B 21/02; H01L 35/32; H01L 35/34

(57) ABSTRACT

A thermoelectric device may include a first substrate, a second substrate, and a plurality of thermoelectric elements positioned between the first and second substrates. The thermoelectric device may also include a first attachment material connecting each thermoelectric element of the plurality of thermoelectric elements to the first substrate, and a second attachment material connecting each thermoelectric element of the plurality of thermoelectric elements to the second substrate. The first attachment material may have a higher liquidus temperature than a liquidus temperature of the second attachment material.

### TECHNICAL FIELD

The present invention relates to a thermoelectric device for high temperature applications and methods for producing and using such thermoelectric devices.

### BACKGROUND

Thermoelectric devices (TEDs) are solid-state devices that produce electrical energy when subjected to a temperature gradient, and produce a temperature gradient when subjected to an electric current. The conversion of a temperature gradient into electrical energy is due to the Seebeck effect, and the conversion of electrical energy into a temperature gradient is due to an inverse reciprocal effect known as the Peltier effect. TEDs include both thermoelectric cooling devices (TECs) and thermoelectric generators (TEGs). A TEC (also known as a Peltier device) is a thermoelectric device that transfers heat from one location to another when an electric current is passed through the device, and a TEG is thermoelectric device that generates an electric current when a temperature gradient is applied across the device.

A TED includes one or more pairs of thermoelectric elements (thermoelements) arranged between two substrates having a metallization pattern that electrically interconnects the thermoelectric elements in series. Any thermally conductive and electrically insulating material (such as ceramics) may be used as the substrates. When operating as a TEC, an electric current directed through the thermoelements produce a temperature difference between the two substrates which may be used to cool or heat an object (or a space). When operating as a TEG, a temperature difference applied between the two substrates may be used to produce electric current. In both modes of operation of a TED (that is, as a TEC and a TEG), the two substrates exist at different temperatures. When a material is heated, it expands by an amount equal to αΔT, where α is the coefficient of thermal expansion (CTE) of a material and ΔT is its increase in temperature. Because the two substrates are at different temperatures during operation of the TED, they tend to expand by different amounts. However, since these two substrates are connected together by thermoelements, relative motion between them is restrained. This restriction in relative motion induces thermomechanical (TM) stresses at the interface between the materials, and causes the TED to warp or bend (similar to a bimetal thermostat). The stresses and warpage may decrease the reliability of the TED.

Embodiments of the current disclosure may alleviate some of the problems discussed above and/or other problems in the art. The scope of the current disclosure, however, is defined by the attached claims, and not by the ability to solve any specific problem.

### SUMMARY

In one aspect, a thermoelectric device is disclosed. The thermoelectric device may include a first substrate and a second substrate, and a plurality of thermoelectric elements positioned between the first and second substrates. The thermoelectric device may also include a first attachment material connecting each thermoelectric element of the plurality of thermoelectric elements to the first substrate, and a second attachment material connecting each thermoelectric element of the plurality of thermoelectric elements to the second substrate. The first attachment material may have a higher liquidus temperature than a liquidus temperature of the second attachment material.

In another aspect, a thermoelectric device is disclosed. The thermoelectric device may include a first substrate and a second substrate. The first substrate may have a lower coefficient of thermal expansion than a coefficient of thermal expansion of the second substrate. The thermoelectric device may also include a plurality of thermoelectric elements positioned between the first and second substrates. The plurality of thermoelectric elements may be connected electrically in series.

In another aspect, a method of making a thermoelectric device is disclosed. The method may include attaching one end of a plurality of thermoelectric elements to a first substrate using a first attachment material, and attaching an opposite end of the plurality of thermoelectric elements to a second substrate using a second attachment material. The first attachment material may have a higher liquidus temperature than a liquidus temperature of the second attachment material.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings of which:

FIG. 1 illustrates an exemplary thermoelectric device.

FIG. 2 is a cross-sectional view of the thermoelectric device of FIG. 1;

FIG. 3 illustrates an exemplary thermoelectric element of the thermoelectric device of FIG. 1 in detail;

FIG. 4A illustrates an exemplary attachment region of a thermoelectric element in the thermoelectric device of FIG. 1;

FIG. 4B illustrates an exemplary support structure of the thermoelectric device of FIG. 1;

FIG. 5A illustrates an exemplary compliant interconnect structure of the thermoelectric device of FIG. 1;

FIG. 5B illustrates another exemplary compliant interconnect structure of the thermoelectric device of FIG. 1;

FIG. 5C illustrates another exemplary compliant interconnect structure of the thermoelectric device of FIG. 1;

FIG. 6A illustrates another exemplary compliant interconnect structure of the thermoelectric device of FIG. 1;

FIG. 6B illustrates another exemplary compliant interconnect structure of the thermoelectric device of FIG. 1; and

FIG. 7 illustrates an exemplary method of making the thermoelectric device of FIG. 1.

### DETAILED DESCRIPTION

While various embodiments of the invention have been shown and described herein, it will be obvious to those skilled in the art that such embodiments are provided by way of example only. Numerous variations, changes, and substitutions may occur to those skilled in the art without departing from the invention.

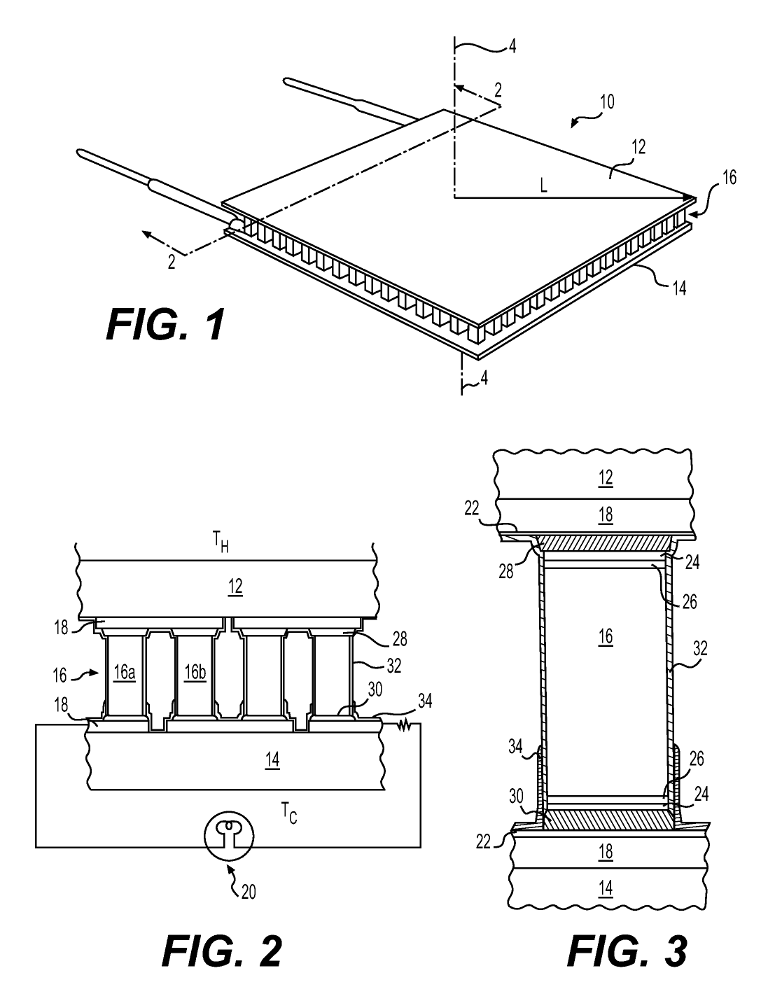

FIG. 1 illustrates a TED 10 that may be used as a TEC or a TEG. FIG. 2 illustrates a cross-sectional view of TED 10 through plane 2-2 of FIG. 1. In the description that follows, reference will be made to both FIGS. 1 and 2. Although the current disclosure can be applied to both TECs and TEGs, for the sake of brevity, only the application of TED 10 as a power generator is described below. TED 10 includes one or more pairs of thermoelements 16 connected electrically in series and thermally in parallel between two substrates 12, 14. Any number of thermoelement 16 pairs may be used in TED 10. When one side of substrate 12 is exposed to a hot temperature (T_{H}) and one side of substrate 14 is exposed to a relatively colder temperature (T_{C}), or vice versa, an electric current is generated through a circuit connecting the thermoelements 16. This current may be used to power an electrical load 20. Since the mechanism of power generation using a thermoelectric generator is well known in the art, this is not described in detail herein. In the description below, the substrate exposed to the higher temperature (that is, substrate 12) will be referred to as the high temperature substrate and the substrate exposed to the lower temperature (that is, substrate 14) will be referred to as the low temperature substrate.

When substrate 12 is exposed to hot temperature (T_{H}) and substrate 14 is exposed to a cold temperature (T_{C}), a region of substrate 12 positioned at a length L from a central axis 4 of TED 10 will tend to expand by an amount Lα₁₂(ΔT_{H}), and a corresponding region of substrate 14 will tend to expand by an amount Lα₁₄(ΔT_{C}). Wherein, α₁₂ and α₁₄ are the coefficient of thermal expansions (CTEs) of substrates 12 and 14 respectively, and ΔT_{H} (ΔT_{H}=T_{H}−Tᵣₒₒₘ) and ΔT_{C} (ΔT_{C}=T_{C}−Lᵣₒₒₘ) are the differences in temperatures of substrates 12 and 14 from room temperature. That is, the relative thermal expansion (uₓ) between the substrates 12 and 14 is L(α₁₂ΔT_{H}−α₁₄ΔT_{C}). Since the thermoelements 16 connected between the substrates 12, 14 prevent free expansion of the substrates 12, 14, TM stresses (shear and normal stresses) are developed causing TED 10 to warp (or bend). The magnitude of the TM stresses depends upon the material properties (modulus of elasticity, elastic limit, etc.) and the dimensions of TED 10 (size, thickness, etc. of the individual layers). In general, the magnitude of the TM stresses increases with the relative thermal expansion (uₛ) between substrates 12 and 14, the size of TED 10, and the stiffness (thickness, modulus of elasticity, etc.) of the substrates 12, 14. A description of these stresses, and their relation to material and dimensional parameters, are described in many Mechanics textbooks and articles (See, for example, “Calculated Thermally Induced Stresses in Adhesively Bonded and Soldered Assemblies,” by E. Suhir, available online at http://catinacc.web.cern.ch/catinacc/articles/Suhir_thermallyInducedStresses.pdf.)

Each pair of thermoelements 16 includes an n-type thermoelement 16a and a p-type thermoelement 16b. As is known in the art, an n-type thermoelement is made of a material that has excess electrons, and a p-type thermoelement 16b is made of a material that has excess holes. Any known thermoelectric material may be used as n-type and p-type thermoelements 16a, 16b. Non-limiting examples of materials used as n-type and p-type thermoelements 16a, 16b include combinations of some or all of Bismuth (Bi), Antimony (Sb), Tellurium (Te), Cerium (Ce), Iron (Fe), Cobalt (Co), Ytterbium (Yb), Manganese (Mn), Palladium (Pd), Tin (Sn), Selenium (Se), and other elements (for example, Bi_{0.5}Sb_{1.5}Te₃, Zn₄Sb₃, CeFe_{3.5}Co_{0.5}Sb₁₂, Yb₁₄MnSb₁₁, MnSi_{1.73}, SnSe, CePd₃, NaCo₂O₄, B-doped Si, B-doped Si_{0.8}Ge_{0.2}, YbAl₃, Si nanowires, La₃Te₄, Skutterudites (for example, Ba—Yb—CoSb₃, Ce—Fe—CoSb₃), etc.). In some embodiments, the n-type and p-type thermoelements 16a, 16b may include different ratios of Bismuth Telluride, Antimony Telluride, and Bismuth Selenium (Bi₂Te₃:Sb₂Te₃:Bi₂Se₃ in the ratio of, for example, 1:3:0 or 10:0:1). In some embodiments, a p-type thermoelement 16b may include Bismuth Antimony Telluride alloy (Bi₂₋ₓSbₓTe₃) and an n-type thermoelement 16b may include a Bismuth Tellurium Selenide alloy (Bi₂Te_{3-y}Se_{y}), where x and y vary between about 1.4-1.6 and about 0.1-0.3 respectively.

In general, substrates 12, 14 may be made of any electrically insulating and thermally conductive material (for example, ceramic, Printed Circuit Boards (PCB) with organic/metal core, etc.). In general, any type of ceramic (Aluminum Nitride (AlN), Alumina (Al₂O₃), Silica (SiO₂) etc.) or PCB (organic core, metal core, flexible PCB, etc.) may be used as substrates 12, 14. Typically, a substrate that is compatible with the operational environment of the TED 10 is used in an application. For example, in an application where T_{H}≧500° C. and T_{C}≦100° C., a ceramic may be used as the high temperature substrate 12 and a PCB may be used as the low temperature substrate 14. Substrates 12 and 14 hold TED 10 together mechanically and electrically insulate the individual thermoelements 16a, 16b from one another and from external mounting surfaces.

Substrates 12, 14 include electrical interconnects 18 (or metallization) that interconnect the thermoelements 16 together in series. Any electrically conductive material (copper, aluminum, etc.) may be used as interconnects 18. These interconnects 18 may be formed on the substrates 12, 14 by any known process. In some embodiments, a deposition process (for example, any thermal deposition, physical vapor deposition (PVD), or a chemical vapor deposition (CVD) technique) may be used to deposit a pattern of a conductive material on substrate 12, 14 as interconnect 18. In some embodiments, a direct bonded copper substrate may be used as substrates 12, 14. In these embodiments, a foil of copper (or another conductive material) may be co-fired and sintered with a ceramic to form a layer of metallization on a substrate. The layer of metallization may then be etched to form the desired pattern of interconnect 18. Although not discussed herein, one or more coatings (barrier layers, wetting layers, etc.) may be provided (plated, coated, etc.) between one or both of substrates 12 and 14 and the interconnect 18. Non-limiting examples of materials that may be used as the coatings may include Titanium (Ti), Titanium Tungsten (TiW), Nickel (Ni), Platinum (Pt), Tantalum (Ta), and TaN (Tantalum Nitride).

FIG. 3 illustrates an enlarged view of a region of TED 10 showing the attachment of a thermoelement 16 (16a or 16b) to the substrates 12, 14 in more detail. In the discussion below, reference will be made to FIGS. 2 and 3. The exposed surface of interconnects 18 may include one or more coatings 22. These coatings 22 may prevent oxidation of interconnects 18. Any known oxidation prevention material may be used for this coating 22. In some embodiments, a layer of Nickel (Ni) and/or Gold (Au) may be used as the oxidation resistant coating 22. These coatings 22 may be provided by any means known in the art (deposition, plating, etc.) and may have any thickness. In some embodiments, a 1-10 micrometer (micron) layer of Ni and/or a 0.1-1 micron layer of Au may be provided on interconnect 18 by electroless plating to serve as coating 22. Although FIG. 3 illustrates coating 22 as being provided on the interconnect 18 of both substrates 12 and 14, in some embodiments, the coating 22 may be provided on only one substrate 12 or 14.

A plurality of thermoelement 16 pairs (each pair includes an n-type thermoelement 16a and a p-type thermoelement 16b) are attached to interconnects 18 such that the thermoelements 16 are arranged thermally in parallel and electrically in series between the substrates 12, 14. These thermoelements 16 may be attached to one or both of the substrates 12, 14 by any method (e.g., brazing, soldering, high temperature adhesives, etc.). Prior to attachment, one or more coatings may be applied to the top and bottom surfaces of the thermoelements 16 to protect diffusion (e.g., thermal, etc.) of the attachment material into the thermoelement 16 and/or to improve attachment. For an n-type thermoelement 16a, these coatings may include a layer 26 of Zirconium (Zr) or Hafnium (Hf) followed by a layer 24 of Titanium (Ti). For p-type thermoelements 16b, the coatings may include a layer 26 of Zirconium (Zr) or Hafnium (Hf) followed by a layer 24 of Nickel (Ni). In general, the thickness of layer 26 may be between about 10-30 microns and the thickness of layer 24 may be between about 80-120 microns. Any method may be used to apply these layers on the thermoelements 16. Conventionally, thermoelements 16 are prepared in a wafer form from a bulk thermoelectric material. In some embodiments, foils that make the layers 24 and 26 may be placed on either side of the thermoelectric wafer and pressed together (under pressure, temperature, current, etc.) to join them. In some embodiments, processes such as hot pressing or spark plasma sintering (SPS) may be used to join the foils to the wafer. However, it is also contemplated that one or both of the layers 24, 26 may be applied on the top and bottom surfaces of the thermoelements 16 by other known processes such as deposition, plating, etc. The wafer may then be diced into discrete thermoelements 16 with the layers 24, 26 on the top and bottom surface.

Any dicing process known in the art may be used to dice the wafer. In some embodiments, the wafers may be diced using a diamond blade, wire saw, or a laser. In some applications, some or all of these dicing techniques may induce microscopic cracks or other microstructural damage at the cut edges. In some applications, these damage sites may act as stress concentrators and form crack initiation sites during subsequent processing or in application. Therefore, in some embodiments, a more benign dicing process (e.g., electrical discharge machining or EDM) may be used for dicing. EDM may minimize damage to the cut edges of the wafer.

An attachment material 28 may be used to attach the thermoelements 16 to the high temperature substrate 12 and an attachment material 30 may be used to attach the thermoelements 16 to the low temperature substrate 14. Attachment materials 28 and 30 may include any braze or solder material or a high temperature conductive adhesive. In some embodiments, attachment material 28 and 30 may include the same material. In some embodiments, the attachment material on the low temperature side of TED 10 (that is, attachment material 30) may have a lower liquidus temperature than the attachment material on the high temperature side 28 (that is, attachment material 28). As is known, the liquidus temperature of an alloy is the temperature at which the alloy completely melts, and the solidus temperature is the temperature at which melting of the alloy begins. At temperatures between the solidus and the liquidus temperatures, the alloy consists of a slurry of solid and liquid phases. For a eutectic alloy, the solidus and the liquidus temperature are the same, and for a non-eutectic alloy, the liquidus temperature is higher than the solidus temperature.

In some embodiments, an attachment material 28 in the form of a braze material is placed between substrate 12 and the thermoelement 16. The assembly may then be heated to a temperature above the liquidus temperature of the braze material (and below a temperature that detrimentally affects substrate 12), and cooled to attach the substrate 12 to the thermoelement 16. Typically, braze materials have a liquidus temperature greater than about 450° C. Any known braze material and brazing process may be used to attach thermoelement 16 to substrate 12. Exemplary braze materials that may be used as attachment material 28 are listed in publication titled “List of brazing alloys,” available online at http://en.wikipedia.org/wiki/List_of_brazing_alloys. This document is incorporated by reference herein. In some embodiments, an Aluminum alloy or a Silver (Ag) Copper (Cu) Nickel (Ni) alloy may be used as the attachment material 28. In some higher temperature applications (e.g., 1000° C. and higher), a brazing alloy such as a Palladium (Pd) Silver (Ag) alloy or a Gold (Au) Silver (Ag) alloy may be used as the attachment material 28.

In applications where TED 10 is intended for use in a high temperature application, after attachment of the thermoelements 16 to the substrate 12, the exposed surfaces of the high temperature substrate 12 and the thermoelements 16 may be coated with an sublimation inhibition coating 32. Any suitable material may be used as coating 32. In some embodiments, materials such as Alumina (Al₂O₃), Silicon Nitride (SiN), Zirconium Oxide (ZrO), Titanium Oxide (TiO₂), etc. may be used as coating 32. Any suitable process (for example, a deposition process such as ALD, CVD, PVD, a dip coating process such as sol-gel process, etc.) may be used to deposit coating 32. In some embodiments, the surface of the thermoelements 16 that will be attached to substrate 14 may be masked prior to application of the coating 32. In some embodiments, coating 32 on this attachment surface may be stripped after application.

The exposed surfaces of the thermoelements 16 may then be attached to the low temperature substrate 14 to form TED 10. In general, any attachment material 30 and process (brazing, soldering, adhesives, etc.) may be used to attach substrate 14 to the thermoelements 16. Attachment material 30 may be the same as, or may be different from, attachment material 28. In some embodiments, attachment material 28 may be a braze material and attachment material 30 may be a solder material. Soldering (like brazing) is a process by which a filler material is melted and used to attach two parts together. The difference between soldering and brazing is in the temperature of the heating process. Soldering generally occurs at temperatures less than about 450° C., and brazing generally occurs at temperatures over about 450° C. Therefore a braze material has a liquidus temperature >450° C. and a solder material has a liquidus temperature <450° C. An attachment material 30 in the form of a solder material may be placed between substrate 14 and thermoelements 16 and the assembly heated above the liquidus temperature of the solder material and cooled to attach substrate 14 to the thermoelements 16. Exemplary solder materials that may be used as attachment material 30 are listed in publication titled “Solder,” available online at http://en.wikipedia.org/wild/Solder. This document is incorporated by reference herein. In some embodiments, a low temperature solder that has a liquidus temperature below about 200° C. may be used as attachment material 30. In some embodiments, an Indium (In) Tin (Sn) solder alloy which has a liquidus temperature between about 118-145° C. may be used as attachment material 30. In some embodiments, a higher temperature solder such as eutectic Lead (Pb) Tin (Sn) or eutectic Gold (Au) Tin (Sn) may be used as the attachment material 30.

In some embodiments, the sides of the substrates 12 and 14 that face each other and the exposed surface of the thermoelements 16 may be coated with a high temperature polymer coating 34 such as Parylene (for example, Parylene-C, Parylene-N, Parylene-HT, etc.) to protect the substrates and to prevent corrosion. In some embodiments, the coating 34 may be selectively applied over one of the substrates (for example, the low temperature substrate 14) to prevent the coating 34 from being exposed to temperatures above its safe operating temperature (glass transition temperature, etc.). In some embodiments, the coating 34 may extend over the base of thermoelements 16 to cover attachment material 30. When TED 10 is used in a high temperature application, the temperature in the vicinity of attachment material 30 may approach its liquidus temperature (or its solidus temperature). In such applications, enclosing the attachment material 30 with coating 34 may prevent the molten (or semi-liquid) attachment material 30 from flowing out, or from being squeezed out, from between the substrate 14 and the thermoelements 16. In some embodiments, the height of coating 34 on the thermoelements 16 may be such that the temperature of the coating 34 does not exceed its safe operating temperature.

The TEDs 10 of the current disclosure may be configured to reduce TM stresses induced during operation. As explained previously, the magnitude of the induced TM stresses increases with the thermal expansion mismatch (uₓ) between the high and low temperature substrates 12 and 14 during operation. Although not discussed herein, TM stresses are also induced in TED 10 during fabrication. For example, cool-down from melting temperature of attachment material 30 to room temperature induces TM stresses in TED 10 at room temperature. However, over time, a substantial portion of these fabrication related TM stresses dissipates due to time dependent relaxation processes (such as, creep) that occur in the attachment materials 28, 30. Assuming that the residual fabrication induced TM stresses in TED 10 at room temperature are small, the ratio of thermal expansion of the two substrates at their operating temperatures (that is, α₁₂ΔT_{H}/α₁₄ΔT_{C}) is an indicator of the TM stresses in TED 10 during operation. If this ratio is one, then the thermal expansions of substrates 12 and 14 are the same at their operating temperatures and the induced TM stresses are the lowest.

If the ratio of the CTEs of the substrates (that is, α₁₄/α₁₂) approach the inverse of their temperature rise during operation (that is, ΔT_{H}/ΔT_{C}), the TM stresses at their operating temperatures will be low. For example, if the high temperature substrate 12 operates at 800° C. (ΔT_{H}=800° C.−20° C.=780° C.) and the low temperature substrate 14 operates at 100° C. (ΔT_{C}=100° C.−20° C.=80° C.), then ΔT_{H}/ΔT_{C}=9.75. In such an application, if the ratio α₁₄/α₁₂ is also equal to 9.75, the induced TM stresses during operation will be the lowest (it may not be zero because of manufacturing induced TM stresses and stresses due to CTE mismatch between other parts of TED 10). However, in practice, it may not be always possible to select substrates having a ratio of CTEs equal to the inverse of their temperature rise. Therefore, generally, the high temperature substrate 12 may be selected to have a lower CTE than the low temperature substrate 14 so that their thermal expansion mismatch at operating temperature is reduced. For example, if the high temperature substrate 12 is Silicon Nitride (α≅3 ppm/° C.) and the low temperature substrate 14 is a PCB having a CTE of about 20 ppm/° C., the TM stresses during operation will be low since α₁₄/α₁₂=6.67.

Alternatively or additionally, in some embodiments, the attachment material (28 and/or 30) between the substrates and the thermoelements 16 may be selected such that the thermal expansion mismatch between the substrates 12, 14 at their operating temperature is tolerated. Under constant load or stress, materials undergo progressive inelastic deformation over time. This time dependent deformation is called creep. Creep is accompanied by stress relaxation in the material. While creep is negligible for a material at low homologous temperatures (temperature of a material expressed as a fraction of its melting temperature in the Kelvin scale), creep is significant in a material at high homologous temperatures (typically above 0.5 T_{homologous}) and high stresses. Since the melting temperature of a solder material is relatively low, its homologous temperature is relatively high at typical TED operating temperatures. For example, a solder material having a melting (or liquidus) temperature of about 300° C. is at a homologous temperature of about 0.65 (T_{ambient}/T_{melting}) at an ambient temperature of 100° C. In embodiments of TED 10 where attachment material 30 is a solder material, solder creep and the resulting stress relaxation relieves at least a portion of the TM stresses in TED 10 at operating temperature. In some embodiments of TED 10, a solder material having a melting temperature such that its homologous temperature during operation is greater than or equal to about 0.5 may be selected as attachment material 30.

In some embodiments, a solder that is above its solidus temperature during operation may be selected as attachment material 30. Since a solder above its solidus temperature is a slurry of solid and liquid phases, it may permit relative thermal expansion between the high and low temperature substrates 12, 14 during operation and thus reduce TM stresses. In some embodiments, a solder that is above its liquidus temperature during operation may be selected as attachment material 30. Since a solder above its liquidus temperature will be in a liquid state during operation, substrates 12 and 14 may be decoupled at operating temperature. In such embodiments, encasing the attachment material 30 using coating 34 may prevent the soft or molten solder from being squeezed out from the gap between the thermoelement 16 and the substrate 14.

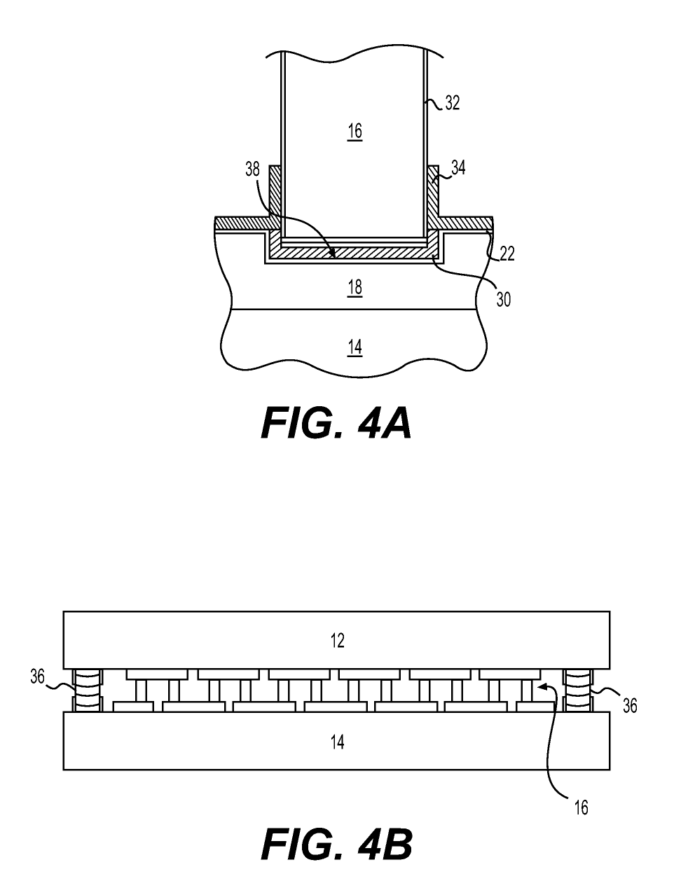

In some embodiments, TED 10 may include features configured to serve as a reservoir for attachment material 30. FIG. 4A illustrates an embodiment of TED 10 in which a trench 38 is provided on interconnects 18 of the low temperature substrate 14 to serve as a reservoir for the attachment material 30. In such embodiments, trench 38 may be fabricated on interconnect 18 using standard microelectronic fabrication techniques such as masking and etching. The trench 38 may serve as a reservoir to collect the pool of molten or softened solder at operating temperatures. Although FIG. 4A illustrates the trench 38 as being formed on the interconnect 18 of substrate 14, this not a limitation. It is also contemplated that, in some embodiments, trench 38 may be formed additionally or alternatively on interconnect 18 of substrate 12.

As illustrated in FIG. 4B, in some embodiments, a mechanical support structure, such as standoffs 36, may be provided as a support between substrates 12 and 14 to transmit mechanical loads between the substrates 12, 14. In applications where TED 10 is compressed between components, the standoffs 36 may prevent the attachment materials 28, 30 from being squeezed out from between the substrates 12, 14. In general, any structure that transmits load between substrates 12 and 14 may be used as standoffs 36. Preferably, standoff 36 may be substantially thermally insulating or have a low thermal conductance. In some embodiments, standoffs 36 may include springs and other flexible structures, such as pogo pins, expanding cylindrical tubes, etc.

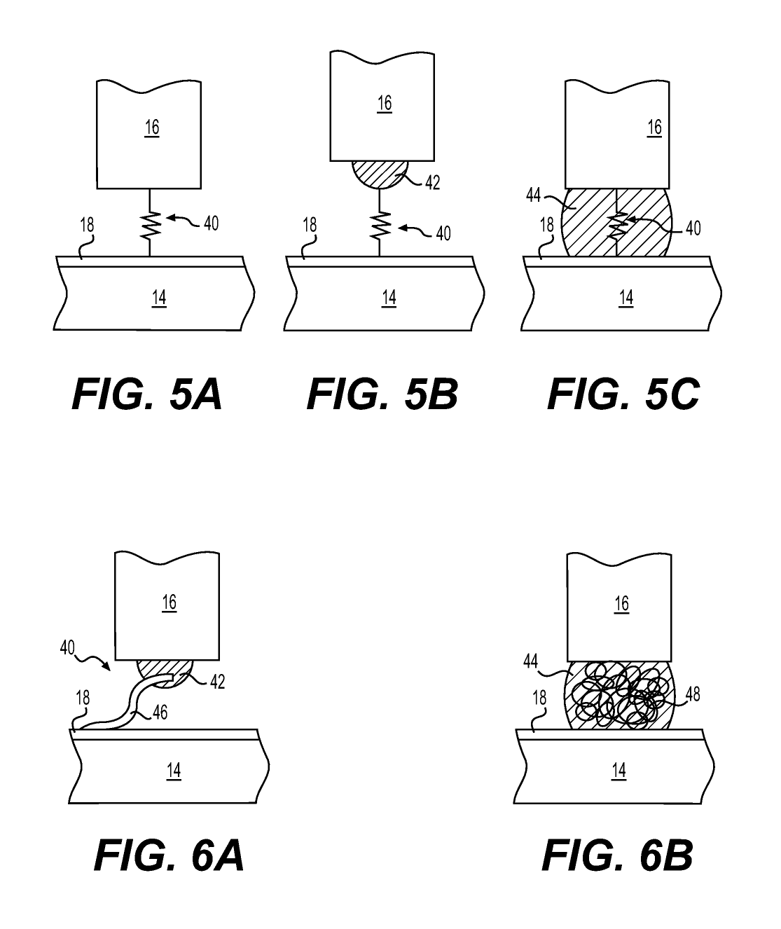

In some embodiments, TED 10 may include a compliant interconnect structure between the thermoelements 16 and one or both of the substrates 12, 14. FIG. 5A schematically illustrates an embodiment of TED 10 with a compliant interconnect 40 between thermoelement 16 and the low temperature substrate 14. Although FIG. 5A illustrates the compliant interconnect 40 as being positioned on the low temperature side of TED 10 (that is, between thermoelement 16 and the low temperature substrate 14), in some embodiments, the compliant interconnect 40 may additionally or alternatively be positioned on the high temperature side of TED 10.

In some embodiments, compliant interconnect 40 may be attached to thermoelement 16 and the substrates (12 or 14) using attachment materials (such as, for example, braze or solder materials, adhesives). In some embodiments, as illustrated in FIG. 5B, one end of the compliant interconnect 40 may be integrally formed with the interconnect 18 (or the thermoelement 16), and the other end may be attached to the thermoelement 16 (or the interconnect 18) using an attachment medium 42. Attachment medium 42 may include, among others, solders, brazes, or adhesives. In some embodiments, as illustrated in FIG. 5C, a conductive filler 44 may enclose the compliant interconnect 40 to improve the electrical and thermal conductivity between the thermoelement 16 and the substrate 14. In some embodiments, conductive filler 44 may include a conductive polymer or a polymer filled with conductive material. The compliant interconnect 40 may permit relative thermal expansion between the substrates 12, 14, thus reducing TM stresses in TED 10.

Any flexible structure (for example, springs, beams, etc.) may be used as the compliant interconnect 40. In some embodiments, as illustrated in FIG. 6A, a flexible beam 46 fabricated on interconnect 18 using IC fabrication techniques may be used as compliant interconnect 40. In some embodiments, a pattern of stressed metal may be deposited and released from a sacrificial layer to form the flexible beam 46. Since such flexible structures and methods to form these structures are known in the art, they are not described herein (see, for example, “Stress-Engineered Compliant Interconnects,” Nanopackaging: Nanotechnologies and Electronic Packaging, James, E. Morris, section 21.3). FIG. 6B illustrates another embodiment of TED 10 with a wire mesh 48 positioned between thermoelement 16 and the substrate 14 to act as a compliant interconnect. Wire mesh 48 may include a structure made up of one or more strands of conductive wires that may be crumpled to form a volume of interconnected material. The wire mesh 48 may be connected between the substrates 12 and 14 to form a compliant interconnect. In some embodiments, a conductive filler 44 that encases the wire mesh 48 may improve the conductivity between substrates 12 and 14.

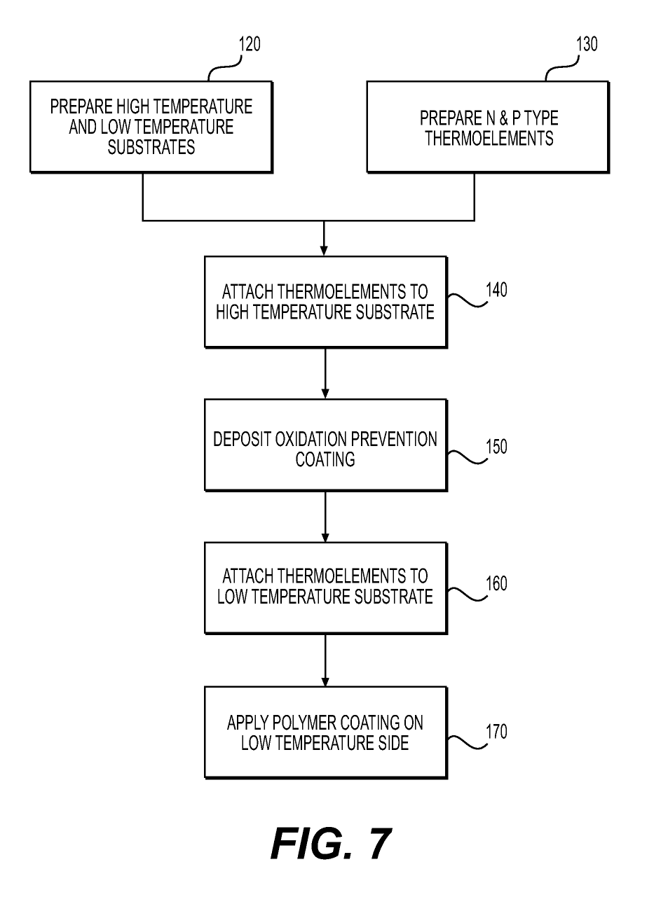

FIG. 7 illustrates a method of making TED 10. In the discussion below, reference will also be made to FIG. 3. In step 120, high and low temperature substrates (12, 14) are prepared. Preparation of the substrates may include selecting suitable substrate materials and depositing adhesion layers (if any) and interconnect 18 pattern on the substrates. As discussed above, in some embodiments, the low temperature substrate 14 may be selected to have a higher CTE than the high temperature substrate 14. In step 130, the p-type and n-type thermoelements 16a, 16b may be prepared. In some embodiments, these thermoelements may be prepared by compacting (e.g., hot pressing, HPS, etc.) suitable thermoelectric materials (with foils that form the coating layers 24 and 26 on either side) into wafers and then dicing them into suitably sized pieces. The thermoelements 16 may be attached to the high temperature substrate 12 using an attachment material 28 in the form of a braze material (step 140). An oxidation prevention coating 32 may then be deposited on the exposed surfaces of substrate 12 and the thermoelements 16 using a deposition process (step 150).

The thermoelements may then be attached to the low temperature substrate using an attachment material 30 in the form of a solder material (step 160). A polymer coating 34 may be applied to the low temperature side of TED 10 (step 170). Any known deposition or dipping process (e.g., CVD) may be used to apply coating 34. In some embodiments, the coating 34 may enclose the attachment material 30 to prevent squeeze out of the attachment material from between the thermoelements 16 and the substrate 14.

It should be understood from the foregoing that, while particular implementations have been illustrated and described, various modifications can be made thereto and are contemplated herein. It is also not intended that the invention be limited by the specific examples provided within the specification. While the invention has been described with reference to the aforementioned specification, the descriptions and illustrations of the embodiments herein are not meant to be construed in a limiting sense. Furthermore, it shall be understood that all aspects of the invention are not limited to the specific depictions, configurations or relative proportions set forth herein which depend upon a variety of conditions and variables. Various modifications in form and detail of the embodiments of the invention will be apparent to a person skilled in the art. It is therefore contemplated that the invention shall also cover any such modifications, variations and equivalents.

1. A thermoelectric device, comprising:
a first ceramic substrate having a first surface;
a second ceramic substrate having a second surface, the second substrate having a different coefficient of thermal expansion than the first substrate;
a plurality of thermoelectric elements extending between the first surface of the first substrate and the second surface of the second substrate;
a first attachment material connecting each thermoelectric element of the plurality of thermoelectric elements to the first surface of the first substrate; and
a second attachment material connecting each thermoelectric element of the plurality of thermoelectric elements to the second surface of the second substrate, wherein the first attachment material has a higher liquidus temperature than the second attachment material.

2. The device of claim 1, wherein the first attachment material is a braze material, and the second attachment material is a solder material.

3. The device of claim 1, wherein the first substrate has a lower coefficient of thermal expansion than the second substrate.

4. The device of claim 1, wherein the second attachment material has a liquidus temperature below about 200° C.

5. The device of claim 1, wherein the second attachment material is positioned on a trench formed on the second substrate, the trench forming a reservoir for molten second attachment material.

6. The device of claim 1, further including a polymer layer selectively coating the second surface and encasing the second attachment material without coating the first surface.

7. The device of claim 1, further including one or more mechanical support structures connecting the first substrate and the second substrate, the mechanical support structures being separate from the plurality of thermoelectric elements.

8. The device of claim 1, wherein the plurality of thermoelectric elements includes one or more pairs of a p-type thermoelectric element and an n-type thermoelectric element, and wherein the plurality of thermoelectric elements includes one or more coating layers at an interface with the first attachment material and at an interface with the second attachment material.

9. The device of claim 8, wherein the one or more coating layers on the p-type thermoelectric element include a layer of zirconium and layer of nickel, and the one or more coating layers on the n-type thermoelectric element include a layer of zirconium and layer of titanium.

10. A thermoelectric device, comprising:
a first substrate and a second substrate, wherein the first substrate has a lower coefficient of thermal expansion than the second substrate;
a plurality of thermoelectric elements positioned between the first and second substrates, wherein the plurality of thermoelectric elements include p-type thermoelectric elements and n-type thermoelectric elements;
a first attachment material coupling a first end of each thermoelectric element of the plurality of thermoelectric elements to the first substrate;
a second attachment material coupling a second end of each thermoelectric element to the second substrate, wherein the first attachment material has a higher liquidus temperature than the second attachment material; and
a polymer layer selectively coating a surface of the second substrate facing the first substrate and encasing the second attachment material without coating a surface of the first substrate facing the second substrate.

11. (canceled)

12. The device of claim 10, wherein the first attachment material is a braze material, and the second attachment material is a solder material.

13. The device of claim 10, further including a compliant interconnect structure positioned between each thermoelectric element and at least one of the first substrate and the second substrate.

14. The device of claim 10, further including an oxide coating layer selectively coating a side of the first substrate facing the second substrate and exposed external surfaces of the plurality of thermoelectric elements without coating a side of the second substrate facing the first substrate.

15. (canceled)

16. The device of claim 13, wherein the compliant interconnect structure includes one of a spring, a beam, and a wire mesh.

17. A method of making a thermoelectric device, comprising:
attaching a first end of each thermoelectric element of a plurality of thermoelectric elements to a first surface of a first substrate using a first attachment material;
after attaching the first end, depositing an oxide coating on the first surface of the first substrate and exposed surfaces of each thermoelectric element;
after the deposition, attaching a second end of each thermoelectric element to a second surface of a second substrate using a second attachment material, wherein the first attachment material has a higher liquidus temperature than the second attachment material; and
providing a polymer layer to selectively coat the second surface of the second substrate and the second attachment material without coating the first surface of the first substrate.

18. The method of claim 17, wherein the first attachment material is a braze material, and the second attachment material is a solder material.

19. The method of claim 17, wherein the first substrate has a lower coefficient of thermal expansion than a coefficient of thermal expansion of the second substrate.

20. (canceled)

21. The device of claim 10, further including multiple coatings on surfaces of each thermoelectric element that interface with the first attachment material and the second attachment material, wherein
the multiple coatings of each p-type thermoelectric element includes (a) an approximately 10-30 micron thick layer of zirconium or hafnium and (b) an approximately 80-120 micron thick layer of nickel, and
the multiple coatings of each n-type thermoelectric element includes (c) an approximately 10-30 micron thick layer of zirconium and (d) an approximately 80-120 micron thick layer of titanium.

22. The device of claim 10, wherein the liquidus temperature of the first attachment material is above 450° C. and the liquidus temperature of the second attachment is below 450° C., and wherein the polymer layer includes parylene.

23. The method of claim 17, wherein the plurality of thermoelectric elements includes p-type thermoelectric elements and n-type thermoelectric elements, and the method further includes:
depositing a layer of zirconium and a layer of nickel on the first and second ends of each p-type thermoelectric element prior to attaching the p-type thermoelectric element to the first and second surfaces; and
depositing a layer of zirconium and a layer of titanium on the first and second ends of each n-type thermoelectric element prior to attaching each n-type thermoelectric element to the first and second surfaces.
